(19) United States
(12) Patent Application Publication
(10) Pub. No.: US 2016/0248228 A1
(43) Pub. Date: Aug. 25, 2016

(54) SURFACE-EMITTING SEMICONDUCTOR LASER, SURFACE-EMITTING SEMICONDUCTOR LASER ARRAY, SURFACE-EMITTING SEMICONDUCTOR LASER DEVICE, OPTICAL TRANSMISSION DEVICE, AND INFORMATION PROCESSING DEVICE

(71) Applicant: FUJI XEROX CO., LTD., Tokyo (JP)

(72) Inventors: Takashi KONDO, Kanagawa (JP); Akemi MURAKAMI, Kanagawa (JP); Kazutaka TAKEDA, Kanagawa (JP); Naoki JOGAN, Kanagawa (JP); Junichiro HAYAKAWA, Kanagawa (JP); Jun SAKURAI, Kanagawa (JP)

(73) Assignee: FUJI XEROX CO., LTD., Tokyo (JP)

(21) Appl. No.: 14/844,702

(22) Filed: Sep. 3, 2015

(30) Foreign Application Priority Data
Feb. 25, 2015 (JP) 2015-034851

(51) Int. Cl. H01S 5/22; G02B 26/10; G02B 19/00; H01S 5/183; H04B 10/50

(52) U.S. Cl. CPC H01S 5/222; H01S 5/183; H01S 5/18377; H01S 5/18336; H04B 10/503; G02B 19/0052; G02B 26/10

(57) ABSTRACT

A surface-emitting semiconductor laser includes a substrate; a first semiconductor multilayer film reflector stacked on the substrate; an active region stacked on or above the first semiconductor multilayer film reflector; a second semiconductor multilayer film reflector stacked on or above the active layer; a cavity extension region interposed between the first semiconductor multilayer film reflector and the active region or between the second semiconductor multilayer film reflector and the active region; and a carrier block layer interposed between the cavity extension region and the active region. The carrier block layer includes a first carrier block layer and a second carrier block layer. The first and second carrier block layers have a larger band gap than the active region and the cavity extension region. The first carrier block layer has a larger band gap than the second carrier block layer.

### CROSS-REFERENCE TO RELATED APPLICATIONS

This application is based on and claims priority under 35 USC 119 from Japanese Patent Application No. 2015-034851 filed Feb. 25, 2015.

### BACKGROUND

(i) Technical Field

The present invention relates to a surface-emitting semiconductor laser, a surface-emitting semiconductor laser array, a surface-emitting semiconductor laser device, an optical transmission device, and an information processing device.

(ii) Related Art

Surface-emitting semiconductor lasers are light-emitting devices capable of emitting a laser beam in a direction perpendicular to the substrate and therefore readily formed in a two-dimensional array. Thus, surface-emitting semiconductor lasers have been increasingly used as a light source of a printer, an image-forming apparatus, optical communication, or the like.

### SUMMARY

According to an aspect of the invention, there is provided a surface-emitting semiconductor laser including a substrate; a first semiconductor multilayer film reflector stacked on the substrate, the first semiconductor multilayer film reflector including alternating pairs of a high-refractive-index layer having a higher refractive index and a low-refractive-index layer having a lower refractive index; an active region stacked on or above the first semiconductor multilayer film reflector; a second semiconductor multilayer film reflector stacked on or above the active layer, the second semiconductor multilayer film reflector including alternating pairs of a high-refractive-index layer having a higher refractive index and a low-refractive-index layer having a lower refractive index; a cavity extension region interposed between the first semiconductor multilayer film reflector and the active region or between the second semiconductor multilayer film reflector and the active region, the cavity extension region having an optical thickness larger than an oscillation wavelength, the cavity extension region enabling a cavity length to be increased; and a carrier block layer interposed between the cavity extension region and the active region, the carrier block layer including a first carrier block layer and a second carrier block layer, the first and second carrier block layers having a larger band gap than the active region and the cavity extension region, the first carrier block layer having a larger band gap than the second carrier block layer.

### BRIEF DESCRIPTION OF THE DRAWINGS

Exemplary embodiments of the present invention will be described in detail based on the following figures, wherein:

FIG. 1A is a graph illustrating the single-longitudinal mode of a λ-cavity surface-emitting semiconductor laser, where the vertical axis represents reflectivity and the horizontal axis represents wavelength;

FIG. 1B is a graph illustrating the multi-longitudinal mode of a long-cavity surface-emitting semiconductor laser;

FIG. 2 is a schematic cross-sectional view of a long-cavity surface-emitting semiconductor laser according to a first exemplary embodiment of the invention;

FIGS. 3A and 3B illustrate the conduction band structures of regions that cover an active region and a carrier block layer, where FIG. 3A illustrates the band structure according to a comparative example and FIG. 3B illustrates the band structure according to the first exemplary embodiment;

FIG. 4 illustrates the relationship between the band structure of a carrier block layer and a standing wave;

FIGS. 5 and 6 illustrate the relationship between the carrier block layer according to a second exemplary embodiment of the invention and a standing wave;

FIG. 7 is a schematic cross-sectional view of a long-cavity surface-emitting semiconductor laser according to a third exemplary embodiment of the invention;

FIGS. 8A and 8B are schematic cross-sectional views of surface-emitting semiconductor laser devices including a surface-emitting semiconductor laser according to an exemplary embodiment of the invention as an optical member;

FIG. 9 illustrates an example of a light source device including a surface-emitting semiconductor laser according to an exemplary embodiment of the invention; and

FIG. 10 is a schematic cross-sectional view of an optical transmission device including the surface-emitting semiconductor laser device illustrated in FIG. 8A.

### DETAILED DESCRIPTION

Exemplary embodiments of the invention are described below with reference to the attached drawings. Surface-emitting semiconductor lasers (i.e., vertical-cavity surface-emitting lasers, hereinafter abbreviated as “VCSELs”) have been used as a light source of a communication apparatus or an image-forming apparatus. There has been a demand for a single-mode, high-light-output VCSEL in order to further increase printing speed and the like in future. In order to achieve a single-mode (i.e., fundamental transverse mode) operation using the oxidation-confinement-type structure of the related art, it is necessary to set the diameter of an oxidation aperture to 2 to 3 μm. However, setting the diameter of an oxidation aperture to 2 to 3 μm makes it difficult to achieve a single-mode light output of 3 mW or more consistently. Setting the diameter of an oxidation aperture to be larger than 2 to 3 μm enables high light output to be achieved, but multi-mode (i.e., higher transverse mode) oscillation may disadvantageously occur. Thus, great expectations are placed on long-cavity VCSELs as a technology in which the light output is increased by increasing the diameter of an oxidation aperture while the single-mode operation is maintained.

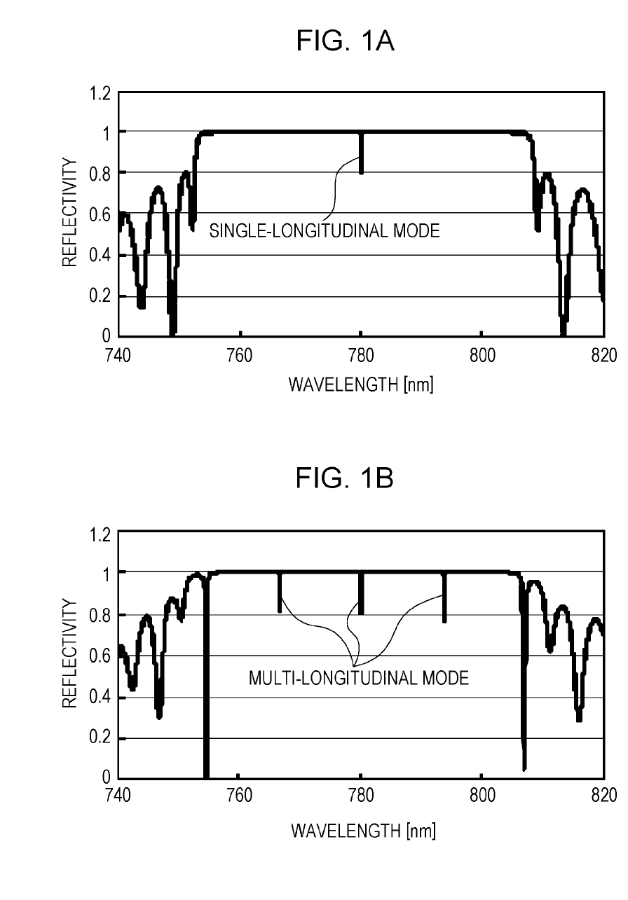

In a long-cavity VCSEL, a spacer layer having a thickness several times to several tens of times the oscillation wavelength λ is interposed between a light-emitting region of an ordinary λ-cavity VCSEL and one of the semiconductor multilayer film reflectors (i.e., DBRs) of the λ-cavity VCSEL in order to increase the length of the cavity, and thereby the amount of loss in the higher transverse mode is increased. As a result, single-mode oscillation can be achieved even when the diameter of an oxidation aperture is set to be larger than that of the ordinary λ-cavity VCSEL. The ordinary λ-cavity VCSELs operate in the single-longitudinal mode as illustrated in FIG. 1A because they have a large longitudinal-mode spacing (i.e., free spectral range). In contrast, long-cavity VCSELs have a small longitudinal-mode spacing due to extension of the cavity, and multiple longitudinal modes (i.e., standing waves) are present inside the cavity as illustrated in FIG. 1B. Long-cavity VCSELs are operated in a longitudinal mode selected from the multiple longitudinal modes. In other words, plural oscillation wavelengths are present in a reflection bandwidth having a reflectivity of 97% or more. The invention relates to such long-cavity VCSELs having the multi-longitudinal mode.

A selective-oxidation-type long-cavity VCSEL is described below as an example. It should be noted that the drawings are scaled for ease of visualization of the features of the invention and the dimension of the device illustrated in the drawings is not always the same as that of the actual device.

### EXEMPLARY EMBODIMENTS

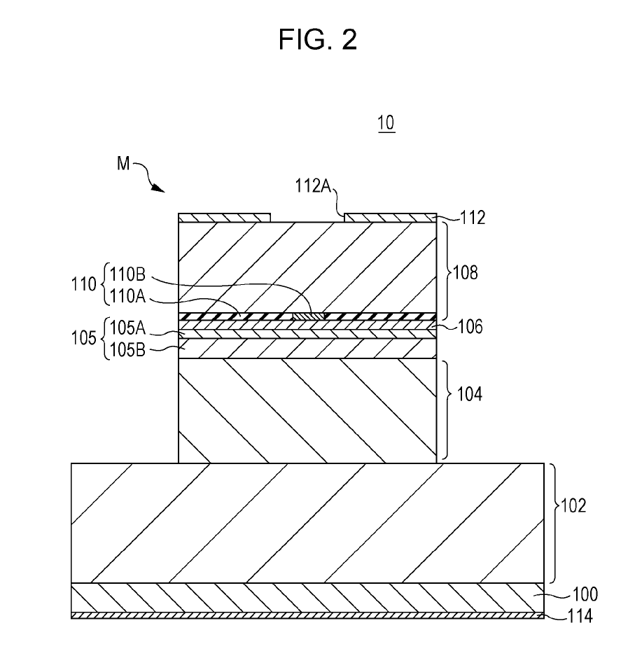

FIG. 2 is a schematic cross-sectional view of a long-cavity VCSEL according to a first exemplary embodiment of the invention. As illustrated in FIG. 2, a VCSEL 10 according to the first exemplary embodiment includes an n-type GaAs substrate 100; an n-type lower distributed Bragg reflector (hereinafter, abbreviated as “DBR”) 102 stacked on the n-type GaAs substrate 100, the lower DBR 102 including alternating pairs of AlGaAs layers having different Al contents; a cavity extension region 104 formed on the lower DBR 102, the cavity extension region 104 enabling the length of the cavity to be increased; an n-type carrier block layer 105 stacked on the cavity extension region 104; an active region 106 formed on the carrier block layer 105, the active region 106 including upper and lower spacer layers and a quantum well layer interposed therebetween; and a p-type upper DBR 108 stacked on the active region 106, the upper DBR 108 including alternating pairs of AlGaAs layers having different Al contents. These semiconductor layers stacked on and above the substrate are deposited by sequential epitaxial growth.

The n-type lower DBR 102 is a multilayer body including pairs of an Al_{0.9}Ga_{0.1}As layer and Al_{0.3}Ga_{0.7}As layer. The thicknesses of the Al_{0.9}Ga_{0.1}As layer and the Al_{0.3}Ga_{0.7}As layer are each set to λ/4nᵣ, where λ represents an oscillation wavelength and nᵣ represents the refractive index of the medium. The lower DBR 102 includes 40 periods of alternating layers of Al_{0.9}Ga_{0.1}As and Al_{0.3}Ga_{0.7}As. The lower DBR 102 is doped with silicon, which serves as an n-type impurity, such that the carrier concentration in the lower DBR 102 is, for example, 3×10¹⁸ cm⁻³.

The cavity extension region 104 is composed of AlGaAs, GaAs, or AlAs whose lattice constant is equal or matches to the lattice constant of the GaAs substrate. In the first exemplary embodiment, for example, the cavity extension region 104 is composed of AlGaAs that does not cause light absorption to occur in order to emit a laser beam at 780 nm. The cavity extension region 105 is, for example, a monolithic layer formed by sequential epitaxial growth and has an optical thickness several times to several tens of times the oscillation wavelength λ, which increases the distance that carriers travel. Thus, the cavity extension region 104 may be set to be n-type, in which the mobility of carriers is high and is therefore interposed between the n-type lower DBR 102 and the active region 106. The thickness of the cavity extension region 104 is set to, for example, about 3 to 4 μm or about 16λ in terms of optical thickness. The n-type doping level in the cavity extension region 104 is set to, for example, 5×10¹⁷. The above-described cavity extension region 104 may also be referred to as “cavity space”.

The carrier block layer 105 is interposed between the cavity extension region 104 and the active region 106. The band gap of the carrier block layer 105 is set to be larger than the band gaps of the cavity extension region 104 and the active region 106. Increasing the height of the barrier created by the carrier block layer 105 reduces the risk of carrier leakage from the active region 106 to the cavity extension region 104 and thereby brings the inside of the active region into a “carrier-rich” state, which increases luminous efficiency. In the first exemplary embodiment, the carrier block layer 105 is constituted by two sublayers, namely, a first carrier block layer 105A and a second carrier block layer 105B. The first carrier block layer 105A is composed of n-type AlAs or AlGaAs. The second carrier block layer 105B is composed of n-type AlGaAs. The carrier block layer is described below in detail.

The lower spacer layer constituting the active region 106 is an undoped Al_{0.6}Ga_{0.4}As layer. The quantum well active layer constituting the active region 106 includes an undoped Al_{0.11}Ga_{0.89}As quantum well sublayer and undoped Al_{0.3}Ga_{0.7}As barrier sublayers. The upper spacer layer constituting the active region 106 is an undoped Al_{0.6}Ga_{0.4}As layer.

The p-type upper DBR 108 is a multilayer body including a p-type Al_{0.9}Ga_{0.1}As layer and an Al_{0.4}Ga_{0.6}As layer. The thicknesses of the Al_{0.9}Ga_{0.1}As layer and the Al_{0.4}Ga_{0.6}As layer are each set to λ/4nᵣ. The upper DBR 108 includes 29 periods of alternating layers of Al_{0.9}Ga_{0.1}As and Al_{0.4}Ga_{0.6}As. The upper DBR 108 is doped with carbon, which serves as a p-type impurity, such that the carrier concentration in the upper DBR 108 is, for example, 3×10¹⁸ cm³. A contact layer composed of p-type GaAs or the like is formed as a top layer of the upper DBR 108. A current confinement layer (i.e., oxide confinement layer) 110 composed of p-type AlAs or AlGaAs is formed as a bottom layer of the upper DBR 108 or inside the bottom layer.

For example, a cylindrical mesa (i.e., columnar structure) M is formed above the substrate 100 by removing a portion of the above-described semiconductor layers which extends from the upper DBR 108 to the lower DBR 102 by etching. In an oxidation step, the current confinement layer 110 and the carrier block layer 105 are exposed at the side surfaces of the mesa M. The current confinement layer 110 is selectively oxidized from the side surfaces of the mesa M. As a result, an oxidized region 110A and a conductive region (i.e., oxidation aperture) 110B surrounded by the oxidized region 110A are formed in the current confinement layer 110. In the oxidation step, the oxidation rate in the AlAs layer is higher than in the AlGaAs layer, and the oxidized region 110A is oxidized from the side surfaces of the mesa M toward the inside of the oxidized region 110A at a substantially constant rate. Thus, the shape of a cross section of the conductive region 110B which is parallel to the substrate is brought into agreement with the outside shape of the mesa M, that is, a circular shape, and the center of the conductive region 110B is substantially aligned with the optical axis of the mesa M. In the long-cavity VCSEL 10, it is possible to set the diameter of the conductive region 110B which is required for achieving the fundamental transverse mode oscillation to be large compared with the ordinary λ-cavity VCSELs. For example, the diameter of the conductive region 110B can be increased to about 7 to 8 μm, which enables light output to be increased.

A circular metal p-side electrode 112, which is formed by depositing Ti/Au or the like, is disposed on the top layer of the mesa M. The p-side electrode 112 is connected to the contact layer constituting the upper DBR 108 so as to come into ohmic contact with the contact layer. A circular light-emitting window 112A is formed in the p-side electrode 112 such that the center of the light-emitting window 112A is aligned with the optical axis of the mesa M. A laser beam is emitted outward through the window 112A. An n-side electrode 114 is disposed on the rear surface of the substrate 100.

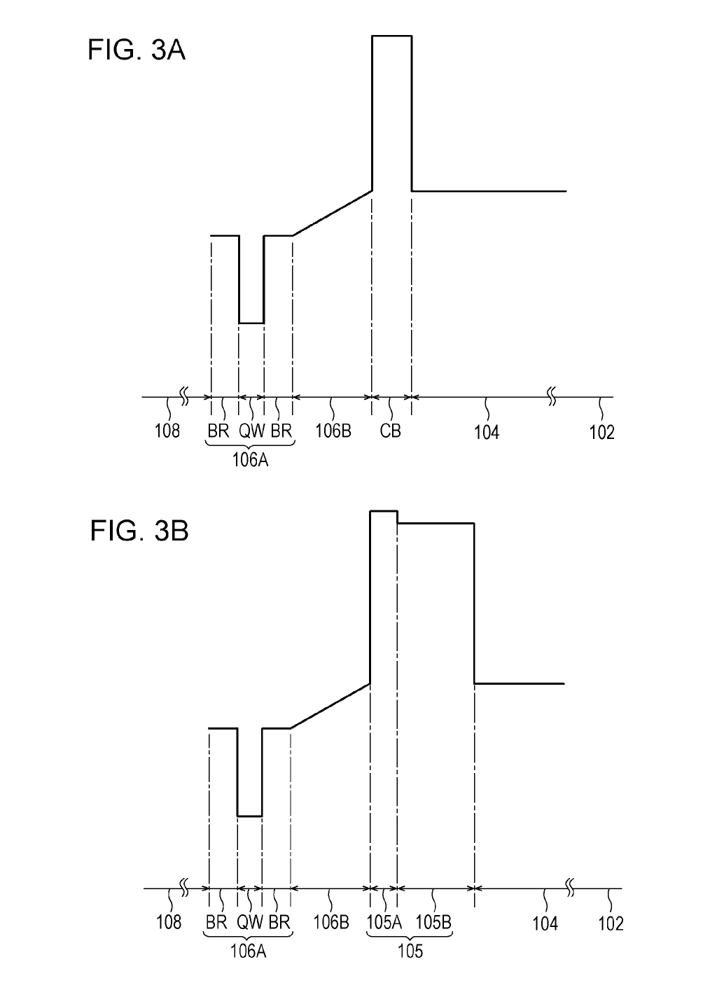

The carrier block layer according to the first exemplary embodiment is described below in detail. In the ordinary VCSELs that do not have a long-cavity structure, it is not necessary to form a carrier block layer because the DBRs have the carrier-confinement effect. On the other hand, in long-cavity VCSELs, absence of a carrier block layer may result in a poor carrier-confinement effect because the Al content in the cavity extension region is not sufficiently high. FIGS. 3A and 3B illustrate the conduction band structures of regions that cover the active region and the carrier block layer, where FIG. 3A illustrates the band structure according to a comparative example and FIG. 3B illustrates the band structure according to the first exemplary embodiment.

As described above, the active region 106 includes the quantum well active layer 106A and the lower spacer layer 106B and the upper spacer layer (not shown in the drawing) between which the quantum well active layer 106A is interposed. The quantum well active layer 106A includes an undoped Al_{0.10}Ga_{0.90}As quantum well sublayer QW and undoped Al_{0.3}Ga_{0.7}As barrier sublayers BR between which the quantum well sublayer QW is interposed. The lower spacer layer 106B is an undoped AlGaAs layer in which the Al content is changed from 30% to 40%. The cavity extension region 104 is composed of n-type Al_{0.40}Ga_{0.60}As. In the comparative example, a carrier block layer CB composed of n-type Al_{0.90}Ga_{0.10}As is interposed between the lower spacer layer 106B and the cavity extension region 104. The carrier block layer CB, having a large band gap, reduces the risk of carrier leakage from the active region 106 to the cavity extension region 104. However, in particular, some carriers excited by thermal energy may leak beyond the barrier created by the carrier block layer CB during high-temperature operation.

The carrier block layer 105 according to the first exemplary embodiment includes a first carrier block layer 105A adjacent to the lower spacer layer 106B and a second carrier block layer 105B adjacent to the first carrier block layer 105A. The band gaps of the first and second carrier block layers 105A and 105B are set to be larger than the band gaps of the active region 106 and the cavity extension region 104. The band gap of the first carrier block layer 105A is set to be larger than the band gap of the second carrier block layer 105B. In other words, when the first carrier block layer 105A is composed of AlₓGa₁₋ₓAs and the second carrier block layer 105B is composed of Al_{y}Ga_{1-y}As, the relationship x>y is satisfied. The larger the band gap of the first carrier block layer 105A, the higher the barrier against carriers. Therefore, the Al content in the first carrier block layer 105A is set to, for example, 0.9<x≦1. The n-type doping level in the first carrier block layer 105A is set to, for example, 1×10¹⁸.

The higher the Al content in the first carrier block layer 105A, the larger the band gap. However, when the Al content in the first carrier block layer 105A is equal to or higher than the Al content in the current confinement layer 110, the first carrier block layer 105A may be disadvantageously oxidized to a degree comparable to that to which the current confinement layer is oxidized in the step of oxidizing the current confinement layer 110. If the first carrier block layer 105A is oxidized than needed, electric resistance may be disadvantageously increased.

The oxidation rate in an Al-containing layer depends on the thickness of the Al-containing layer as well as the Al content in the Al-containing layer. Specifically, the larger the thickness of an Al-containing layer, the higher the oxidation rate in the Al-containing layer. If the first carrier block layer 105A has a larger thickness than the current confinement layer 110, in the worst case, the entirety of the first carrier block layer 105A is oxidized and it becomes impossible to pass a current through the first carrier block layer 105A. Therefore, when the Al content in the first carrier block layer 105A is equal to or higher than the Al content in the current confinement layer 110, the thickness of the first carrier block layer 105A may be set to be smaller than the thickness of the current confinement layer 110 in order to reduce the oxidation rate in the first carrier block layer 105A and thereby minimize the area of the oxidized region in the first carrier block layer 105A. Since the thickness of the current confinement layer 110 is set to, for example, 20 to 30 nm in the ordinary VCSELs, the thickness of the first carrier block layer 105A is set to 15 nm or less (e.g., about 10 nm), that is, for example, half the thickness of the current confinement layer 110 or less.

Reducing the thickness of the first carrier block layer 105A results in a reduction in oxidation rate. However, an excessively small thickness of the first carrier block layer 105A may result in penetration (i.e., tunneling) of the carriers confined within the active region 106 into the first carrier block layer 105A. The penetration of the carriers may occur when the thickness of the first carrier block layer 105A is, for example, 10 nm or less. The penetration of the carriers is more likely to occur when the thickness of the first carrier block layer 105A is a few nanometers. In order to prevent penetration of the carriers from occurring, the second carrier block layer 105B is disposed adjacent to the first carrier block layer 105A. The second carrier block layer 105B is composed of Al_{y}Ga_{1-y}As having a lower Al content than the first carrier block layer 105A. The Al content in the second carrier block layer 105B is set to, for example, 0.9≦y<x. The second carrier block layer 105B has a larger thickness than the first carrier block layer 105A. The total thickness of the first and second carrier block layers 105A and 105B is set such that carriers do not penetrate the first and second carrier block layers 105A and 105B. However, the higher the Al content, the higher the risk that crystal quality is degraded. Thus, the thickness of the second carrier block layer 105B is set such that the total thickness of the first and second carrier block layers 105A and 105B is about 50 nm. The doping level in the second carrier block layer 105B is set to be lower than that in the first carrier block layer 105A, that is, for example, 5×10¹⁷.

In the first exemplary embodiment, dividing the carrier block layer into two sublayers reduces the risk of carrier leakage in the following manner. Forming the first carrier block layer 105A having a relatively large band gap and thereby increasing the height of the barrier created by the first carrier block layer 105A reduce the risk of the carriers confined within the active region 106, which serves as a light-emitting layer, traveling beyond the barrier created by the first carrier block layer 105A even when the carriers are excited by the thermal energy during high-temperature operation. In addition, the second carrier block layer 105B having a large thickness reduces the risk of penetration (i.e., tunneling) of carriers which may occur under the constraint that the thickness of the first carrier block layer 105A is set to be small. This increases the luminous efficiency of the active region 106, in particular, in high-temperature operation. Dividing the carrier block layer into two sublayers also allows the maximum band gap in the carrier block layer and the thickness of the carrier block layer to be independently controlled. This makes it easy to reduce both electric resistance of the device and risk of carrier leakage compared with the case where a single carrier block layer, which is not constituted by the first and second carrier block layers, is formed.

In the first exemplary embodiment, a case where the carrier block layer 105 includes two sublayers 105A and 105B having discontinuous band gaps is described as an example. However, the structure of the carrier block layer 105 is not limited to this. The carrier block layer 105 includes at least the above-described two sublayers 105A and 105B and may further include additional layers. The ranges of the Al contents in the first and second carrier block layers 105A and 105B described above (i.e., 0.9<x≦1, 0.9≦y<x) are merely examples, and the Al contents in the first and second carrier block layers 105A and 105B may be set to be outside the ranges.

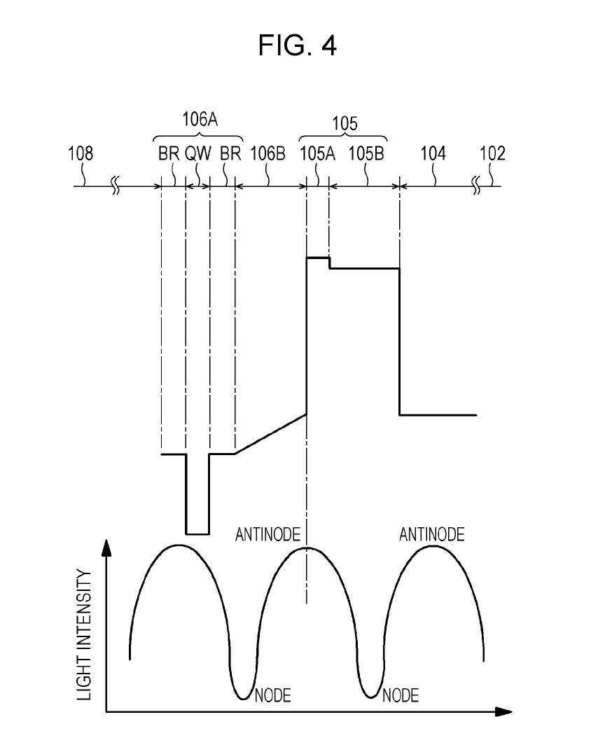

A second exemplary embodiment of the invention is described below. In the second exemplary embodiment, laser characteristics are improved by optimizing the position of a highly doped carrier block layer. FIG. 4 illustrates the relationship between the band structure of the carrier block layer and the distribution of light intensity. Increasing the doping level (i.e., impurity concentration) in the first carrier block layer 105A causes the band structure to shift upward and the height of the barrier to be further increased, which reduces the risk of carrier leakage. Thus, the first carrier block layer 105A may be doped at a level higher than that at which the second carrier block layer 105B is doped. For example, the doping levels in the first and second carrier block layers 105A and 105B are set to 1×10¹⁸ and 5×10¹⁷, respectively. A standing wave is formed inside the cavity between the lower DBR 102 and the upper DBR 108. The light intensity is higher at the antinodes (i.e., points corresponding to odd multiples of λ/4) of the standing wave than at the nodes (i.e., points corresponding to even multiples of λ/4) of the standing wave. If the first carrier block layer 105A, which has a high Al content and a high doping level, is located at the antinode of the standing wave as illustrated in FIG. 4, the amount of light absorbed by the first carrier block layer 105A is increased, which deteriorates laser characteristics.

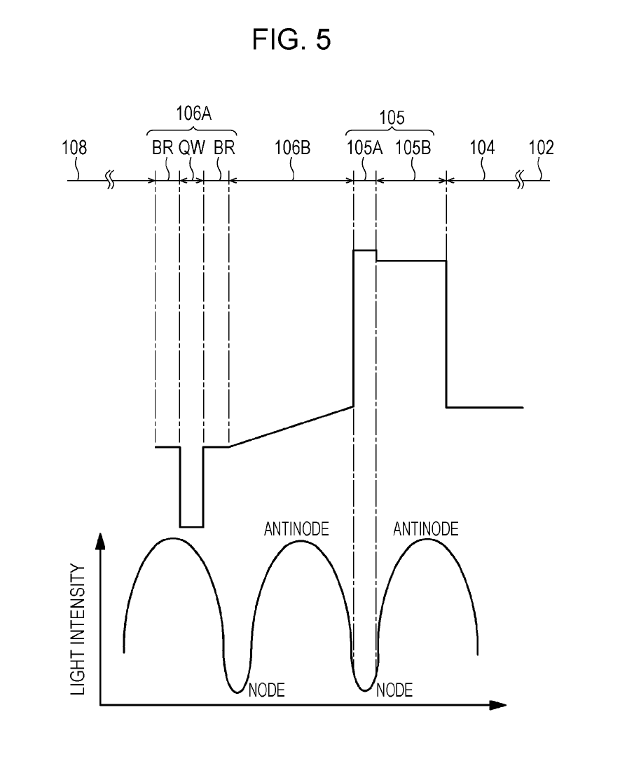

FIG. 5 illustrates a first method for optimizing the position of the highly doped first carrier block layer according to the second exemplary embodiment. The position of the first carrier block layer 105A is adjusted such that the first carrier block layer 105A is located at the node of the standing wave as illustrated in FIG. 5. In other words, the node of the standing wave is located within the first carrier block layer 105A. Since the light intensity is lower at nodes than at antinodes, the amount of light absorbed by the first carrier block layer 105A, which has a high impurity concentration, becomes small compared with the case where the first carrier block layer 105A is located at the antinode of the standing wave, which improves laser characteristics. The first carrier block layer 105A can be located at the node of the standing wave by, for example, controlling the thickness of the lower spacer layer 106B constituting the active region 106. The first carrier block layer 105A may be located at any position other than the antinodes of the standing wave. That is, the first carrier block layer 105A is not necessarily located at the node of the standing wave. For example, the first carrier block layer 105A may be located between the antinode and node of the standing wave. The first carrier block layer 105A is not necessarily located at the node of the standing wave and may be located at any position between the point corresponding to half the maximum light intensity of the standing wave or about half the maximum light intensity of the standing wave and the node of the standing wave. In other words, the first carrier block layer 105A is located within a region where the light intensity of the standing wave is lower than half the maximum light intensity of the standing wave.

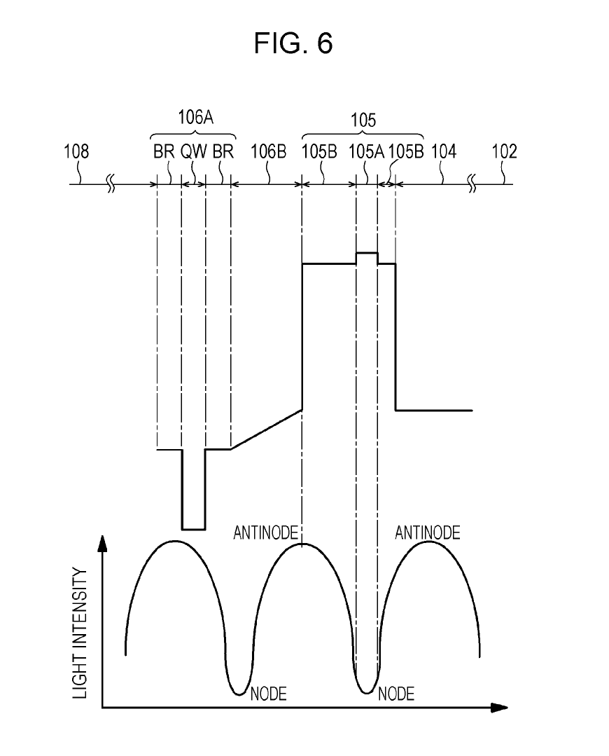

FIG. 6 illustrates a second method for optimizing the position of the highly doped first carrier block layer according to the second exemplary embodiment. In the second method, as illustrated in FIG. 6, the first carrier block layer 105A is located at the node of the standing wave and, in contrast to the first method, the first carrier block layer 105A is formed inside the second carrier block layer 105B. That is, the first carrier block layer 105A is interposed between the active-region-side part of the second carrier block layer 105B and the cavity-extension-region-104-side part of the second carrier block layer 105B. In the second method, the thickness of the lower spacer layer 106B constituting the active region 106 is not changed as in the first method. Therefore, the optical thickness of the active region 106 is equal to the oscillation wavelength λ or the integral multiple of the oscillation wavelength λ, and the boundary between the lower spacer layer 106B and the second carrier block layer 105B (i.e., boundary at which refractive index changes) is located at the antinode of the standing wave. This makes it easy to achieve resonance at the oscillation wavelength. The boundary between the lower spacer layer 106B and the second carrier block layer 105B may be displaced from the antinode of the standing wave so as to be located between the point corresponding to half the maximum light intensity of the standing wave or about half the maximum light intensity of the standing wave and the antinode of the standing wave. In other words, the boundary between the lower spacer layer 106B and the second carrier block layer 105B may be located within a region where the light intensity of a standing wave is higher than half the maximum light intensity of the standing wave. When the boundary is located between the point corresponding to half the maximum light intensity of the standing wave or about half the maximum light intensity of the standing wave and the antinode of the standing wave, it becomes easy to achieve resonance at the oscillation wavelength compared with the case where the boundary is located between the point corresponding to half the maximum light intensity of the standing wave or about half the maximum light intensity of the standing wave and the node of the standing wave. In FIG. 6, the boundary between the lower spacer layer 106B and the second carrier block layer 105B is not necessarily located at the antinode of the standing wave and may be located at any position between the point corresponding to half the maximum light intensity of the standing wave or about half the maximum light intensity of the standing wave and the antinode of the standing wave. The first carrier block layer 105A may be located at any position other than the antinodes of the standing wave. That is, the first carrier block layer 105A is not necessarily located at the node of the standing wave. For example, the first carrier block layer 105A may be located between the antinode and node of the standing wave. The first carrier block layer 105A is not necessarily located at the node of the standing wave and may be located at any position between the point corresponding to half the maximum light intensity of the standing wave or about half the maximum light intensity of the standing wave and the node of the standing wave. In FIG. 6, the cavity-extension-region-104-side part of the second carrier block layer 105B may be omitted. When the cavity-extension-region-104-side part of the second carrier block layer 105B is formed, it is disposed such that the boundary between the cavity extension region 104 and the cavity-extension-region-104-side part of the second carrier block layer 105B is located between the point corresponding to half the maximum light intensity of the standing wave or about half the maximum light intensity of the standing wave and the antinode of the standing wave. This makes it easy to achieve resonance at the oscillation wavelength compared with the case where the boundary is located between the point corresponding to half the maximum light intensity of the standing wave or about half the maximum light intensity of the standing wave and the node of the standing wave. Locating the boundary at the antinode of the standing wave further makes it easy to achieve resonance at the oscillation wavelength. In the second exemplary embodiment, when the first carrier block layer 105A is composed of AlₓGa₁₋ₓAs and the second carrier block layer 105B is composed of Al_{y}Ga_{1-y}As, the relationship x>y is not necessarily satisfied as in the first exemplary embodiment. The values of x and y may be determined such that the first and second carrier block layers 105A and 105B are not oxidized to a degree comparable to that to which the oxide confinement layer is oxidized. By forming the first and second carrier block layers 105A and 105B in the above-described manner, the electric resistances of the first and second carrier block layers 105A and 105B do not become as high as that of the oxide confinement layer. Furthermore, setting the impurity concentration in the first carrier block layer 105A to be higher than the impurity concentration in the second carrier block layer 105B causes the band structure to be shift upward and the height of the barrier to be increased, which reduces the risk of carrier leakage.

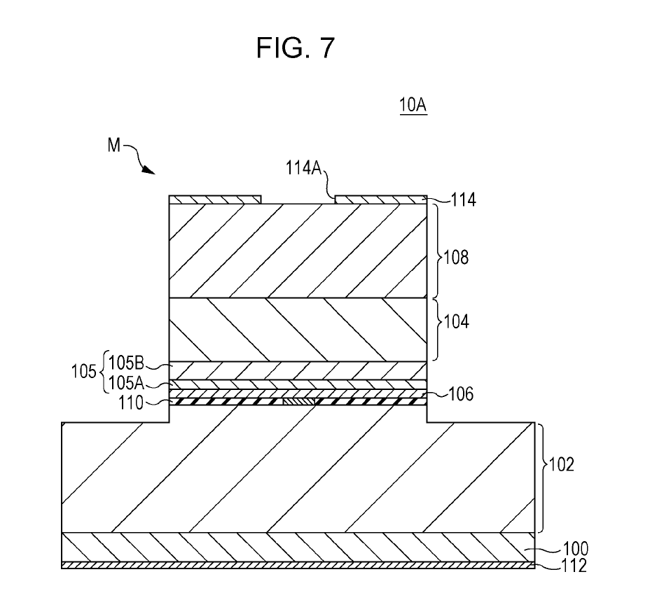

A third exemplary embodiment of the invention is described below. FIG. 7 is a schematic cross-sectional view of a long-cavity VCSEL 10A according to the third exemplary embodiment. In the third exemplary embodiment, a p-type lower DBR 102 is stacked on a p-type GaAs substrate 100. A low-refractive-index layer constituting the lower DBR 102 which is adjacent to an active region 106 or a portion of the low-refractive-index layer is replaced by a current confinement layer 110. An n-type carrier block layer 105 is stacked on the active region 106. An n-type cavity extension region 104 is stacked on the carrier block layer 105. An n-type upper DBR 108 is stacked on the cavity extension region 104. A p-side electrode 112 is disposed on the rear surface of the substrate 100. An n-side electrode 114 is disposed on the top of the upper DBR 108. A circular emission window 114A is formed in the n-side electrode 114. In the third exemplary embodiment, a mesa M may be formed by performing etching until a portion of the lower DBR 102 is removed and the current confinement layer 110 is exposed from the side surfaces of the mesa M.

Exemplary embodiments of the invention are described above in detail. The invention is not limited by a specific exemplary embodiment and various modifications and changes may be made within the scope of the invention described in claims.

While the lower DBR 102 and the upper DBR 108 are composed of AlGaAs in the above-described exemplary embodiments, the pairs of a high-refractive-index layer and a low-refractive-index layer may be composed of semiconductor materials other than AlGaAs. For example, when the oscillation wavelength is set to be large, DBRs may be composed of GaAs; the high-refractive-index layer may be composed of GaAs and the low-refractive-index layer may be composed of AlGaAs.

While a selective-oxidation-type long-cavity VCSEL is described as an example in the above-described exemplary embodiments, the insulation region may be formed by performing injection of proton ions instead of selective oxidation. In such a case, formation of a mesa above the substrate may be omitted.

While a laser beam is emitted from the top of the mesa in the above-described exemplary embodiments, formation of a mesa may be omitted and a laser beam may be emitted from the rear surface of the substrate. In such a case, the reflectivity of the lower DBR 102 is set to be lower than the reflectivity of the upper DBR 108, and an emission window is formed in the n-side electrode 114.

While the n-side electrode 114 is disposed on the rear surface of the substrate in the above-described exemplary embodiments, the n-side electrode 114 may be disposed so as to be directly connected to the lower DBR 102. In such a case, the substrate 100 may be composed of a semi-insulating material.

A buffer layer may optionally be interposed between the GaAs substrate 100 and the lower DBR 102 as needed. While a GaAs-based VCSEL is described as an example in the above-described exemplary embodiments, the above-described exemplary embodiments may also be applied to other types of long-cavity VCSELs including Group III-V semiconductors other than GaAs. While a single-spot VCSEL is described as an example in the above-described exemplary embodiments, the above-described exemplary embodiments may also be applied to multi-spot VCSELs including a number of mesas (i.e., light-emitting portions) disposed on a substrate and VCSEL arrays. In particular, the structure of the carrier block layer according to the above-described exemplary embodiments may be applied to multi-spot VCSELs, which are operated at high temperatures, in an effective manner.

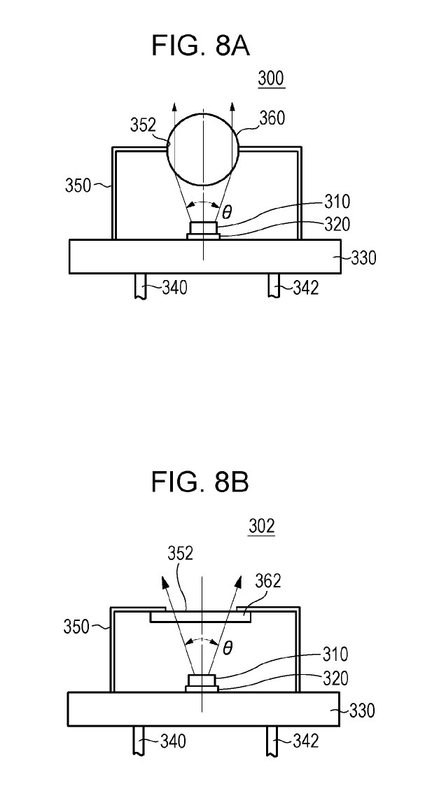

Next, a surface-emitting semiconductor laser device, an optical information processing device, and an optical transmission device that include the long-cavity VCSEL according to the exemplary embodiment of the invention are described with reference to the attached drawings. FIG. 8A is a cross-sectional view of a surface-emitting semiconductor laser device in which the VCSEL and an optical member are packaged. In the surface-emitting semiconductor laser device 300, a chip 310 including the long-cavity VCSEL disposed thereon is fixed to a disk-shaped metal stem 330 with a conductive adhesive 320. Conductive leads 340 and 342 are inserted into through-holes (not illustrated in the drawing) formed in the stem 330. The lead 340 is electrically connected to the n-side electrode of the VCSEL, and the lead 342 is electrically connected to the p-side electrode of the VCSEL.

A rectangular hollow cap 350 is fixed to the stem 330 including the chip 310. A ball lens 360 serving as an optical member is fixed inside an opening 352 formed at the center of the cap 350. The optical axis of the ball lens 360 is positioned so as to be aligned with substantially the center of the chip 310. When a forward voltage is applied between the leads 340 and 342, the chip 310 emits a laser beam in the vertical direction. The distance between the chip 310 and the ball lens 360 is controlled such that the ball lens 360 is positioned within a region corresponding to the angle θ of divergence of the laser beam emitted by the chip 310. Optionally, a photodetector or a temperature sensor may be disposed inside the cap in order to monitor the light-emitting state of the VCSEL.

FIG. 8B illustrates the structure of another surface-emitting semiconductor laser device. A surface-emitting semiconductor laser device 302 illustrated in FIG. 8B includes a flat glass 362 instead of the ball lens 360. The flat glass 362 is fixed inside the opening 352 formed at the center of the cap 350. The flat glass 362 is positioned such that the center of the flat glass 362 is substantially aligned with the center of the chip 310. The distance between the chip 310 and the flat glass 362 is controlled such that the diameter of the opening of the flat glass 362 entirely covers a region corresponding to the angle θ of divergence of the laser beam emitted by the chip 310.

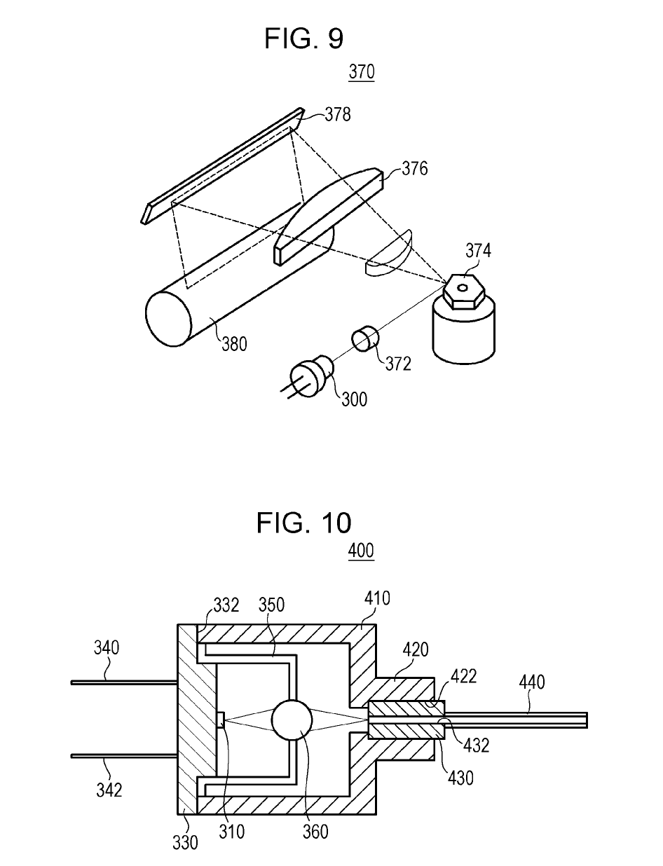

FIG. 9 illustrates an example of an optical information processing device that includes the VCSEL serving as a light source. An optical information processing device 370 includes the surface-emitting semiconductor laser device 300 or 302 including the long-cavity VCSEL packaged therein as illustrated in FIG. 8A or 8B; a collimator lens 372 through which a laser beam emitted by the surface-emitting semiconductor laser device 300 or 302 enters; a polygon mirror 374 that rotates at a constant speed and reflects a bundle of light beams, which is passed through the collimator lens 372, at a certain angle of divergence; an fθ lens 376 through which the laser beam reflected by the polygon mirror 374 enters and enables a reflecting mirror 378 to be irradiated with the laser beam; a linear reflecting mirror 378; and a photoreceptor drum (i.e., recording medium) 380 on which a latent image is formed on the basis of the light reflected by the reflecting mirror 378. The VCSEL according to the exemplary embodiment of the invention may be used as a light source of an optical information processing device, such as a copying machine or a printer, that includes an optical system that condenses a laser beam emitted by the VCSEL on a photoreceptor drum and a mechanism that scans the photoreceptor drum with the condensed laser beam.

FIG. 10 is a cross-sectional view of an optical transmission device that includes the surface-emitting semiconductor laser device illustrated in FIG. 8A. An optical transmission device 400 includes a stem 330; a cylindrical housing 410 fixed to the stem 330; a sleeve 420 integrally formed at an end of the housing 410; a ferrule 430 held inside an opening 422 formed in the sleeve 420; and an optical fiber 440 held by the ferrule 430. A flange 332 is formed on the stem 330 in the circumferential direction. The other end of the housing 410 is fixed to the flange 332. The ferrule 430 is precisely positioned inside the opening 422 of the sleeve 420, and thereby the optical axis of the optical fiber 440 is aligned with the optical axis of the ball lens 360. A core wire of the optical fiber 440 is held inside a through-hole 432 formed in the ferrule 430.

A laser beam emitted from the surface of the chip 310 is condensed by the ball lens 360, and the condensed light enters the core wire of the optical fiber 440 and is thereby transmitted. Although the ball lens 360 is used in the above example, lenses other than a ball lens, such as a biconvex lens and a planoconvex lens, may also be used instead. The optical transmission device 400 may optionally include a driving circuit that applies an electric signal between the leads 340 and 342. The optical transmission device 400 may optionally include a receiving unit that receives an optical signal via the optical fiber 440.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A surface-emitting semiconductor laser comprising:
a substrate;
a first semiconductor multilayer film reflector stacked on the substrate, the first semiconductor multilayer film reflector including alternating pairs of a high-refractive-index layer having a higher refractive index and a low-refractive-index layer having a lower refractive index;
an active region stacked on or above the first semiconductor multilayer film reflector;
a second semiconductor multilayer film reflector stacked on or above the active layer, the second semiconductor multilayer film reflector including alternating pairs of a high-refractive-index layer having a higher refractive index and a low-refractive-index layer having a lower refractive index;
a cavity extension region interposed between the first semiconductor multilayer film reflector and the active region or between the second semiconductor multilayer film reflector and the active region, the cavity extension region having an optical thickness larger than an oscillation wavelength, the cavity extension region enabling a cavity length to be increased; and
a carrier block layer interposed between the cavity extension region and the active region, the carrier block layer including a first carrier block layer and a second carrier block layer, the first and second carrier block layers having a larger band gap than the active region and the cavity extension region, the first carrier block layer having a larger band gap than the second carrier block layer.

2. The surface-emitting semiconductor laser according to claim 1, further comprising:
an Al-containing current confinement layer having a larger thickness than the first carrier block layer, wherein an Al content in the first carrier block layer is equal to or higher than an Al content in the current confinement layer.

3. The surface-emitting semiconductor laser according to claim 1,
wherein the second carrier block layer has a larger thickness than the first carrier block layer.

4. The surface-emitting semiconductor laser according to claim 1,
wherein the first carrier block layer has a higher impurity concentration than the second carrier block layer.

5. A surface-emitting semiconductor laser comprising:
a substrate;
a first semiconductor multilayer film reflector stacked on the substrate, the first semiconductor multilayer film reflector including alternating pairs of a high-refractive-index layer having a higher refractive index and a low-refractive-index layer having a lower refractive index;
an active region stacked on or above the first semiconductor multilayer film reflector;
a second semiconductor multilayer film reflector stacked on or above the active layer, the second semiconductor multilayer film reflector including alternating pairs of a high-refractive-index layer having a higher refractive index and a low-refractive-index layer having a lower refractive index;
a cavity extension region interposed between the first semiconductor multilayer film reflector and the active region or between the second semiconductor multilayer film reflector and the active region, the cavity extension region having an optical thickness larger than an oscillation wavelength, the cavity extension region enabling a cavity length to be increased; and
a carrier block layer interposed between the cavity extension region and the active region, the carrier block layer including a first carrier block layer and a second carrier block layer, the first and second carrier block layers having a larger band gap than the active region and the cavity extension region, the first carrier block layer having a higher carrier concentration than the second carrier block layer.

6. The surface-emitting semiconductor laser according to claim 4,
wherein the first carrier block layer is located within a region where the light intensity of a standing wave is lower than half the maximum light intensity of the standing wave, the standing wave being formed between the first semiconductor multilayer film reflector and the second semiconductor multilayer film reflector.

7. The surface-emitting semiconductor laser according to claim 5,
wherein the first carrier block layer is located within a region where the light intensity of a standing wave is lower than half the maximum light intensity of the standing wave, the standing wave being formed between the first semiconductor multilayer film reflector and the second semiconductor multilayer film reflector.

8. The surface-emitting semiconductor laser according to claim 4,
wherein the first carrier block layer is located at a node of a standing wave formed between the first semiconductor multilayer film reflector and the second semiconductor multilayer film reflector.

9. The surface-emitting semiconductor laser according to claim 5,
wherein the first carrier block layer is located at a node of a standing wave formed between the first semiconductor multilayer film reflector and the second semiconductor multilayer film reflector.

10. The surface-emitting semiconductor laser according to claim 4,
wherein the second carrier block layer is interposed between the active region and the first carrier block layer, and
wherein a boundary between the second carrier block layer and the active region is located within a region where the light intensity of a standing wave is higher than half the maximum light intensity of the standing wave, the standing wave being formed between the first semiconductor multilayer film reflector and the second semiconductor multilayer film reflector.

11. The surface-emitting semiconductor laser according to claim 5,
wherein the second carrier block layer is interposed between the active region and the first carrier block layer, and
wherein a boundary between the second carrier block layer and the active region is located within a region where the light intensity of a standing wave is higher than half the maximum light intensity of the standing wave, the standing wave being formed between the first semiconductor multilayer film reflector and the second semiconductor multilayer film reflector.

12. The surface-emitting semiconductor laser according to claim 4,
wherein the second carrier block layer is interposed between the active region and the first carrier block layer, and
wherein a boundary between the second carrier block layer and the active region is located at an antinode of a standing wave formed between the first semiconductor multilayer film reflector and the second semiconductor multilayer film reflector.

13. The surface-emitting semiconductor laser according to claim 5,
wherein the second carrier block layer is interposed between the active region and the first carrier block layer, and
wherein a boundary between the second carrier block layer and the active region is located at an antinode of a standing wave formed between the first semiconductor multilayer film reflector and the second semiconductor multilayer film reflector.

14. The surface-emitting semiconductor laser according to claim 6,
wherein the second carrier block layer is interposed both between the first carrier block layer and the active region and between the first carrier block layer and the cavity extension region, and
wherein a boundary between the active-region-side second carrier block layer and the active region and a boundary between the cavity-extension-region-side of the second carrier block layer and the cavity extension region are each located within a region where the light intensity of a standing wave is higher than half the maximum light intensity of the standing wave, the standing wave being formed between the first semiconductor multilayer film reflector and the second semiconductor multilayer film reflector.

15. The surface-emitting semiconductor laser according to claim 6,
wherein the second carrier block layer is interposed both between the first carrier block layer and the active region and between the first carrier block layer and the cavity extension region, and
wherein a boundary between the active-region-side second carrier block layer and the active region and a boundary between the cavity-extension-region-side of the second carrier block layer and the cavity extension region are each located at an antinode of the standing wave formed between the first semiconductor multilayer film reflector and the second semiconductor multilayer film reflector.

16. The surface-emitting semiconductor laser according to claim 1,
wherein a columnar structure is formed above the substrate, the columnar structure including the current confinement layer and the carrier block layer, and
wherein the current confinement layer and the carrier block layer are exposed from a side surface of the columnar structure in an oxidation step.

17. A surface-emitting semiconductor laser array comprising a plurality of the surface-emitting semiconductor lasers according to claim 1.

18. A surface-emitting semiconductor laser device comprising:
the surface-emitting semiconductor laser according to claim 1; and
an optical member that light emitted by the surface-emitting semiconductor laser enters.

19. An optical transmission device comprising:
the surface-emitting semiconductor laser device according to claim 18; and
a transmission unit that transmits a laser beam emitted by the surface-emitting semiconductor laser device via an optical medium.

20. An information processing device comprising:
the surface-emitting semiconductor laser according to claim 1;
a light-condensing unit that condenses a laser beam emitted by the surface-emitting semiconductor laser on a recording medium; and
a mechanism that scans the recording medium with the laser beam condensed by the light-condensing unit.
